(19) United States
(12) Patent Application Publication
(10) Pub. No.: US 2012/0206137 A1
(43) Pub. Date: Aug. 16, 2012

(54) MONOLITHIC TRI-AXIS AMR SENSOR AND MANUFACTURING METHOD THEREOF

(75) Inventors: Yongyao Cai, Acton, MA (US); Chongwon Byun, Westborough, MA (US); Yang Zhao, Andover, MA (US); Leyue Jiang, Wuxi (CN)

(73) Assignee: MEMSIC, INC., Andover, MA (US)

(21) Appl. No.: 13/194,329

(22) Filed: Jul. 29, 2011

Related U.S. Application Data
(60) Provisional application No. 61/442,497, filed on Feb. 14, 2011.

(30) Foreign Application Priority Data
Apr. 19, 2011 (CN) 201110098286.8

(51) Int. Cl. G01R 33/02

(52) U.S. Cl. 324/252

(57) ABSTRACT

A monolithic tri-axis anisotropic magnetoresistive (AMR) sensor and the method of manufacturing of the AMR sensor are presented. In one embodiment, the monolithic tri-axis AMR sensor includes (a) a substrate, (b) a first horizontal direction sensor disposed on the substrate, (c) a second horizontal direction sensor disposed on the substrate, (d) a third horizontal direction sensor disposed on the substrate, and (e) a flux concentrator disposed on the third horizontal direction sensor, wherein the flux concentrator is in cooperation with the third horizontal direction sensor to realize a function of a Z-axis sensor, such that the Z-axis direction can be effectively measured. The integration of the tri-axis AMR sensor is therefore accomplished. In addition, the integrated tri-axis AMR sensor has low production cost and improved reliability.

### CROSS-REFERENCE TO RELATED APPLICATIONS

This non-provisional application claims priority under 35 U.S.C.§119(e) on U.S. provisional patent application 61/442,497 filed on Feb. 14, 2011 and under 35 U.S.C.§119(a) on Chinese Patent Application No. 201110098286.8 filed in China, P.R.C. on Apr. 19, 2011, by Yongyao CAI, Chongwon BYUN, Yang ZHAO, and Leyue IANG, the disclosure of which are incorporated herein by reference in its entirety.

### FIELD OF THE INVENTION

The present invention relates to a monolithic tri-axis sensor and a manufacturing method thereof, and more particularly to a monolithic tri-axis anisotropic magnetoresistive (AMR) sensor and its manufacturing method.

### BACKGROUND OF THE INVENTION

With the development of sensor technologies, the use of sensors for various applications is increased dramatically. In addition, types of sensors developed are also increased steadily. For example, one of the types is an AMR-based magnetic field sensor (AMR sensor in short hereinafter).

An AMR sensor is shown in U.S. Pat. No. 5,247,278. Such AMR sensor for a low cost consumption application is generally manufactured on a silicon substrate or other substrates through a semiconductor manufacturing technology, one of the important keys lies in a magnetic material having a resistance value changed according to a change of an external magnetic field.

By applying a reliable semiconductor depositing technology, a magnetic thin film may be uniformly deposited on a substrate. However, in order to maintain stable running, the magnetic thin film must be deposited in a magnetic field. In this way, the direction of the magnetic field determines an easy magnetization axis of a magnetic sensor. Generally, the sensing direction of the sensor is perpendicular to the easy magnetization axis, that is, parallel to a hard magnetization axis. Next, the magnetic sensor is formed on a thin film by utilizing a photoetching technology. The magnetic sensor is generally in a long stripe shape, and a long side thereof extends along the easy magnetization axis. This makes realization of multi-axis integration on the same substrate a challenge in a manufacturing process thereof. The sensing direction of the AMR sensor is parallel to a surface of the substrate, so the Z-axis or the perpendicular axis may be generally manufactured on the same silicon chip. Moreover, a stable and uniform magnetic field must be applied in a process of depositing the AMR thin film, so only one easy magnetization axis may be manufactured on the silicon chip once.

Currently, the magnetic sensor is widely used in mobile phones and other mobile devices used as an electronic compass. However, the market of such product is very sensitive to the cost, and a small packaging size is further required. For the AMR sensor, the multi-axis integration is always a challenge. Previously, module level integration is used to package a plurality of sensor chips into the same device along three perpendicular directions, such as the disclosures in U.S. Pat. No. 7,536,909 and U.S. Pat. No. 7,271,586. Those methods are used in production by different vendors, but proved to be difficult to improve process control and reliability and to reduce production cost.

Additionally, U.S. Pat. No. 6,529,114 provides a method for fabricating a two-axis AMR sensor on the same common plane of the same wafer. According to this method, a single AMR depositing procedure is actually used on two axes respectively. Substantially, the two axes have intrinsic anisotropies in the same direction, which is unfavorable to the precise measurement. Ideally, the intrinsic anisotropies of the two axes should be perpendicular to each other.

Therefore, a heretofore unaddressed need exists in the art to address the aforementioned deficiencies and inadequacies.

### SUMMARY OF THE INVENTION

The technical problem to be solved by the present invention is the defect that an existing AMR sensor cannot realize the tri-axis integration; and in one aspect, the present invention is related to a monolithic tri-axis AMR sensor with high reliability and low production cost.

In one aspect of the present invention, a monolithic tri-axis AMR sensor is provided. The monolithic tri-axis AMR sensor includes a substrate, a first horizontal direction sensor, a second horizontal direction sensor, and a third horizontal direction sensor disposed on the substrate respectively, and a flux concentrator disposed on the third horizontal direction sensor, in which the flux concentrator is in cooperation with the third horizontal direction sensor to realize a function of a Z-axis sensor.

In one embodiment, the first horizontal direction sensor is an X-axis sensor, and the second horizontal direction sensor is a Y-axis sensor.

Further, in another embodiment, an insulating layer is disposed between the first, the second as well as the third horizontal direction sensors and the flux concentrator.

In an additional embodiment, the flux concentrator is made of a soft magnetic material.

In one embodiment, the third horizontal direction sensor includes two groups of sensors: a first sensor group and a second sensor group. The first sensor group includes a first AMR magnetoresistive bar and several first current bias conductor bars forming a certain angle with the first AMR magnetoresistive bar. The second sensor group includes a second AMR magnetoresistive bar and several second current bias conductor bars forming a certain angle with the second AMR magnetoresistive bar.

In another embodiment, the first, the second or the third horizontal direction sensor respectively includes at least two groups of sensors.

Further, in a different embodiment, the at least two groups of sensors have the same structure.

In another aspect, the present invention relates to a method for manufacturing a monolithic tri-axis AMR sensor. The method includes following steps:
depositing a first horizontal direction sensor layer on a substrate, in which the direction of an external magnetic field thereof is a first magnetic field direction;
depositing a second horizontal direction sensor layer and a third horizontal direction sensor layer on an area on the substrate out of the first horizontal direction sensor, in which a second direction of the external magnetic field thereof is perpendicular to the first magnetic field direction;
depositing an insulating layer to cover the first, the second as well as the third horizontal direction sensors; and
depositing a flux concentrator on the third horizontal direction sensor.

In one embodiment, after the depositing the first horizontal direction sensor layer on the substrate, a part of the first horizontal direction sensor layer is removed, and a space for the second horizontal direction sensor is left; a protection coating is deposited to cover the remaining part of the first horizontal direction sensor layer; the second and the third horizontal direction sensors are deposited on the entire substrate, in which due to the existence of the protection coating, in a protection area, the second and the third horizontal direction sensor layers are not in contact with the first horizontal direction sensor layer.

In another embodiment, before the depositing the insulating layer, the protection coating and a redundant sensor layer out of the second horizontal direction sensor and the third horizontal direction sensor are further removed.

Compared with the prior art, the present invention, among other things, has the following beneficial effects. In the present invention, the cooperation between the flux concentrator and the third horizontal direction sensor is utilized, thereby effectively measuring the Z-axis direction, so that the integration of the tri-axis AMR sensor become possible. The AMR sensor integration is therefore accomplished. In addition, the integrated tri-axis AMR sensor has a low production cost and maintains high reliability.

Additionally, using the method of manufacturing a monolithic tri-axis AMR sensor according to one embodiment of the present invention is advantageous in the process control, the reliability improvement and the cost reduction. These advantages are important for manufacturing the monolithic tri-axis AMR sensor in large scale.

These and other aspects of the present invention will become apparent from the following description of the preferred embodiment taken in conjunction with the following drawings, although variations and modifications therein may be effected without departing from the spirit and scope of the novel concepts of the disclosure.

### BRIEF DESCRIPTION OF THE DRAWINGS

The accompanying drawings illustrate one or more embodiments of the present invention and together with the written description, serve to explain the principles of the present invention. Wherever possible, the same reference numbers are used throughout the drawings to refer to the same or like elements of an embodiment, and wherein:

FIG. 1 is a perspective view of a flux concentrator being in cooperation with a third horizontal direction sensor in a monolithic tri-axis AMR sensor according to one embodiment of the present invention;

FIG. 2 is a sectional view of FIG. 1; and

FIG. 3 is a schematic view of working principles of a part as shown in FIG. 2.

### DETAILED DESCRIPTION OF THE INVENTION

The present invention is more particularly described in the following examples that are intended as illustrative only since numerous modifications and variations therein will be apparent to those skilled in the art. Various embodiments of the invention are now described in detail. Referring to the drawings, like numbers indicate like components throughout the views. As used in the description herein and throughout the claims that follow, the meaning of “a”, “an”, and “the” includes plural reference unless the context clearly dictates otherwise. Also, as used in the description herein and throughout the claims that follow, the meaning of “in” includes “in” and “on” unless the context clearly dictates otherwise.

Embodiments of the present invention are illustrated in detail hereinafter with reference to the accompanying drawings.

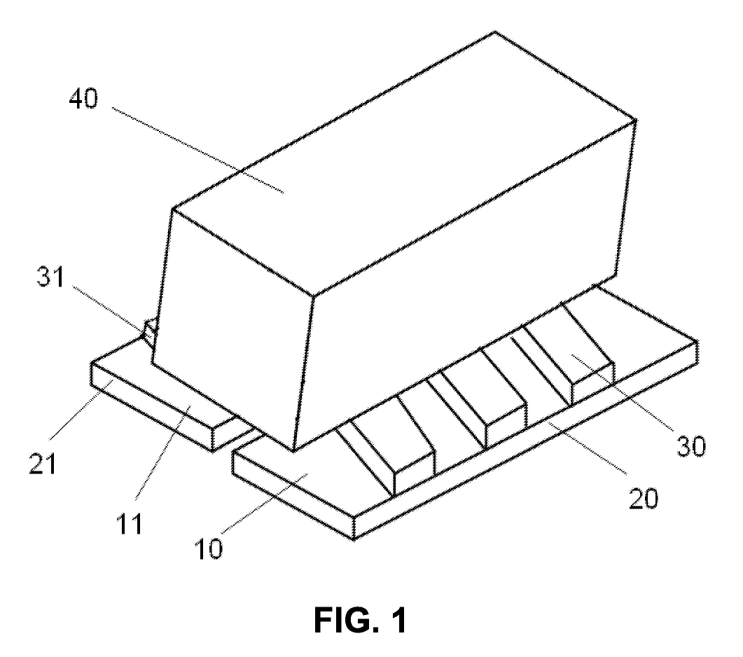

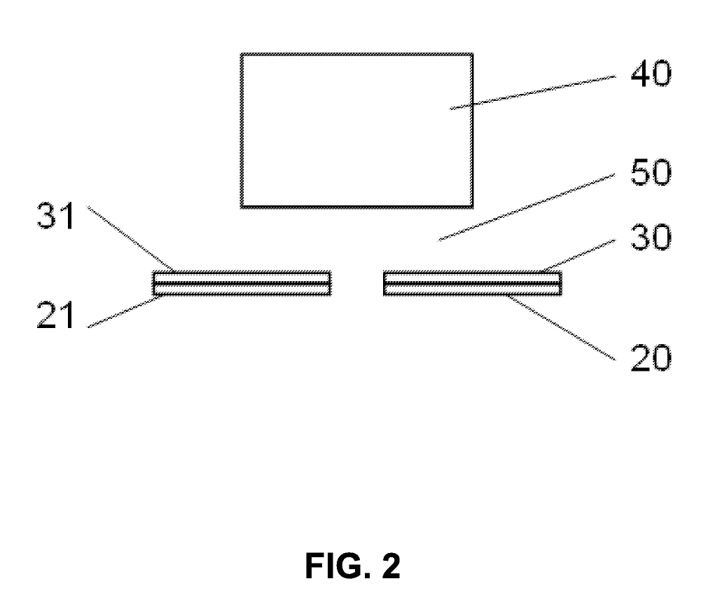

Referring to FIG. 1, an embodiment of the present invention provides a monolithic tri-axis AMR sensor that includes a substrate (not shown), a first horizontal direction sensor (not shown) disposed on the substrate, a second horizontal direction sensor (not shown), a third horizontal direction sensor, and a flux concentrator 40 disposed on the third horizontal direction sensor, in which an insulating layer 50 is disposed between the first, the second as well as the third horizontal direction sensors and the flux concentrator 40 (referring to FIG. 2). The first, the second and the third horizontal direction sensors respectively include at least two groups of sensors. In this embodiment, the third horizontal direction sensor includes two groups of sensors, that is, a first sensor group 10, and a second sensor group 11. Both sensor group 10 and 11 have the same structure. The first sensor group 10 includes a first AMR magneto-resistive bar 20 and several equally-spaced first current bias conductor bars 30 forming a certain angle with the first AMR magneto-resistive bar 20. Similarly, the second sensor group 11 includes a second AMR magneto-resistive bar 21 and several equally-spaced second current bias conductor bars 31 forming a certain angle with the second AMR magneto-resistive bar 21.

The first horizontal direction sensor realizes a function of an X-axis sensor, the second horizontal direction sensor realizes a function of a Y-axis sensor, and the flux concentrator 40 and the third horizontal direction sensor formed of the first sensor group 10 and the second sensor group 11 are in cooperation with each other to realize a function of a Z-axis sensor. A specific realization manner for the function of the Z-axis sensor is obtained with reference to the following contents.

FIG. 2 illustrates a schematic case of a lateral section between the flux concentrator 40 and the third horizontal direction sensor. The flux concentrator 40 is a soft magnetic material bar manufactured on the substrate, and when an external magnetic field perpendicular to a surface of the substrate occurs, the flux concentrator 40 concentrates the external magnetic field and changes the direction of the magnetic field around the concentrator. Patient matters.

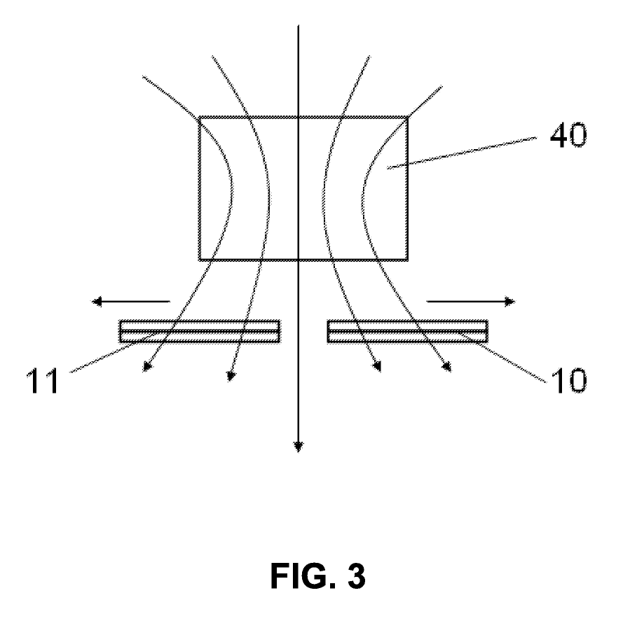

FIG. 3 illustrates the direction of a curved magnetic field flux generated by the flux concentrator when the magnetic field flux enters and leaves the surface of the substrate (the direction of entering or leaving is as shown through an arrow in the drawing). As shown in the drawing, when the perpendicular magnetic field passes through and leaves, a magnetic field component in a horizontal direction is generated around an edge of the flux concentrator 40. At this time, if an AMR sensor is disposed below the flux concentrator 40, the AMR sensor is capable of detecting the magnetic field in a horizontal direction. Therefore, in the present invention, the third horizontal direction sensor is disposed, so the flux concentrator 40 is in cooperation with the third horizontal direction sensor to detect the perpendicular direction (that is, the Z-axis direction).

In a different embodiment, the first, the second as well as the third horizontal direction sensors respectively include more than two groups of sensors. Furthermore, structures of the sensor groups are the same. Each of the sensor groups includes an AMR magneto-resistive bar and several current bias conductor bars forming a certain angle with the AMR magneto-resistive bar. Therefore, one or more bridge structures are constructed, so that a differential signal is detected through a sensor group. In a different embodiment, the current bias conductor bars may be equally spaced.

In another aspect, the present invention relates to a method of manufacturing a monolithic tri-axis AMR sensor. In one embodiment, the method includes following steps:
(a) a first horizontal direction sensor layer is deposited on a substrate, and the direction of an external magnetic field is a first magnetic field direction;
(b) through photoetching and etching, a part of the first horizontal direction sensor layer is removed, and a space of a second horizontal direction sensor remains. During the etching process, a certain thickness of the substrate is removed at an opening part; then, a protection coating is applied on the substrate to cover the remaining part of the first horizontal direction sensor layer;
(c) a second horizontal direction sensor layer and a third horizontal direction sensor layer are deposited on an area on the substrate out of the first horizontal direction sensor, and a second direction of the external magnetic field thereof is perpendicular to the first magnetic field direction. Due to existence of the protection coating, in a protection area, the second and the third horizontal direction sensor layers are not in contact with the first horizontal direction sensor layer;
(d) the protection coating and a redundant sensor layer out of the second horizontal direction sensor and the third horizontal direction sensor are removed by applying a lift-off process;
(e) an insulating layer is deposited to cover the first, the second as well as the third horizontal direction sensors; and
(f) a flux concentrator is deposited on the third horizontal direction sensor.

Alternatively, in another embodiment, the method includes following steps:
(a) a second horizontal direction sensor layer and a third horizontal direction sensor layer are deposited on a substrate, and the direction of an external magnetic field is a second magnetic field direction;
(b) through photoetching and etching, a redundant portion of the second horizontal direction sensor layer and the third horizontal direction sensor layer is removed, and a space of a first horizontal direction sensor remains. During the etching process, a certain thickness of the substrate is removed at an opening part; then, a protection coating is applied on the substrate to cover the remaining part of the second and third horizontal direction sensor layers;
(c) a first horizontal direction sensor layer is deposited on an area on the substrate out of the second and third horizontal direction sensor, and a first direction of the external magnetic field thereof is perpendicular to the second magnetic field direction. Due to existence of the protection coating, in a protection area, the first horizontal direction sensor layers is not in contact with the second and the third horizontal direction sensor layers;
(d) the protection coating and a redundant sensor layer out of the first horizontal direction sensor is removed by applying a lift-off process;
(e) an insulating layer is deposited to cover the first, the second as well as the third horizontal direction sensors; and
(f) a flux concentrator is deposited on the third horizontal direction sensor.

By utilizing a method for depositing a double-AMR thin film according to one embodiment of the present invention, the first and the second horizontal direction sensor layers are manufactured on the same substrate through two different depositing steps. In the process of etching the AMR sensor thin film in the first horizontal direction, the material of the substrate at the opening part is removed, so the AMR sensor layer in the second horizontal direction is not on the same plane as the AMR sensor layer in the first horizontal direction.

Compared with the related art, the cooperation between the flux concentrator and the third horizontal direction sensor is utilized in the present invention, thereby effectively measuring the Z-axis direction, so that the integration of the tri-axis AMR sensor become possible, and AMR sensor integration is therefore accomplished. Furthermore, the integrated tri-axis AMR sensor has low production cost and improved reliability.

Additionally, using the method for manufacturing the monolithic tri-axis AMR sensor according to one embodiment of the present invention is advantageous in the process control, the reliability increase and the cost reduction. These features are very important for manufacturing the monolithic tri-axis AMR sensor according to the present invention in a large scale.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments are chosen and described in order to explain the principles of the invention and their practical application so as to activate others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. A monolithic tri-axis anisotropic magnetoresistive (AMR) sensor, comprising:
(a) a substrate;
(b) a first horizontal direction sensor disposed on the substrate;
(c) a second horizontal direction sensor disposed on the substrate;
(d) a third horizontal direction sensor disposed on the substrate; and
(e) a flux concentrator disposed on the third horizontal direction sensor,
wherein the flux concentrator is in cooperation with the third horizontal direction sensor to realize a function of a Z-axis sensor.

2. The monolithic tri-axis AMR sensor according to claim 1, wherein the first horizontal direction sensor is an X-axis sensor, and the second horizontal direction sensor is a Y-axis sensor.

3. The monolithic tri-axis AMR sensor according to claim 1, wherein an insulating layer is disposed between the first horizontal direction sensor, the second horizontal direction sensor, the third horizontal direction sensor and the flux concentrator.

4. The monolithic tri-axis AMR sensor according to claim 1, wherein the flux concentrator comprises a soft magnetic material.

5. The monolithic tri-axis AMR sensor according to claim 1, wherein the third horizontal direction sensor comprises two groups of sensors:
(a) a first sensor group; and
(b) a second sensor group,
wherein the first sensor group comprises a first AMR magnetoresistive bar and a plurality of first current bias conductor bars forming a certain angle with the first AMR magnetoresistive bar; and the second sensor group comprises a second AMR magnetoresistive bar and a plurality of second current bias conductor bars forming a certain angle with the second AMR magnetoresistive bar.

6. The monolithic tri-axis AMR sensor according to claim 1, wherein the first horizontal direction sensor, the second horizontal direction sensor, and the third horizontal direction sensor comprises at least two groups of sensors, respectively.

7. The monolithic tri-axis AMR sensor according to claim 6, wherein the at least two groups of sensors have the same structure.

8. The monolithic tri-axis AMR sensor according to claim 7, wherein the two groups of sensors comprise:
(a) a first sensor group; and
(b) a second sensor group,
wherein the first sensor group comprises a first AMR magnetoresistive bar and a plurality of first current bias conductor bars forming a certain angle with the first AMR magnetoresistive bar; and the second sensor group comprises a second AMR magnetoresistive bar and a plurality of second current bias conductor bars forming a certain angle with the second AMR magnetoresistive bar.

9. A method for manufacturing the monolithic tri-axis anisotropic magnetoresistive (AMR) sensor, comprising:
(a) depositing a first, a second and a third horizontal direction sensor layers on a substrate;
(b) removing the redundant sensor layer on the substrate on the area defined outside of the first, the second and the third horizontal direction sensor layers;
(c) depositing an insulating layer to cover the first, the second and the third horizontal direction sensors; and
(d) depositing a flux concentrator on the third horizontal direction sensor.

10. The method for manufacturing the monolithic tri-axis AMR sensor according to claim 9, wherein the depositing a first, a second and a third horizontal direction sensors on a substrate step comprises:
(a) depositing the first horizontal direction sensor layer on the substrate, wherein the direction of an external magnetic field thereof is a first magnetic field direction;
(b) after depositing the first horizontal direction sensor layer on the substrate, the redundant portion of the first horizontal direction sensor layer is removed to save a space for the second horizontal direction sensor layer and the third horizontal direction sensor layer;
(c) a protection coating is deposited to cover the remaining part of the first horizontal direction sensor layer; and
(d) depositing the second horizontal direction sensor layer and the third horizontal direction sensor layer on an area on the substrate out of the first horizontal direction sensor, wherein a second direction of an external magnetic field thereof is perpendicular to the first magnetic field direction;

11. The method for manufacturing the monolithic tri-axis AMR sensor according to claim 9, wherein the depositing a first, a second and a third horizontal direction sensor layers step comprises:
(a) depositing the second and the third horizontal direction sensor layers on the substrate, wherein the direction of an external magnetic field thereof is a second magnetic field direction;
(b) after depositing the second and the third horizontal direction sensor layers on the substrate, the redundant portion of the second and the third horizontal direction sensor layers is removed to save a space for the first horizontal direction sensor layer;
(c) a protection coating is deposited to cover the remaining part of the second and the third horizontal direction sensor layers; and
(d) depositing the first horizontal direction sensor layer on an area on the substrate out of the second and the third horizontal direction sensor layers, wherein a first direction of an external magnetic field thereof is perpendicular to the second magnetic field direction.

12. A method of sensing magnetism field, comprising:
(a) providing a monolithic tri-axis anisotropic magnetoresistive (AMR) sensor, comprising:
(i) a substrate;
(ii) a first horizontal direction sensor disposed on the substrate;
(iii) a second horizontal direction sensor disposed on the substrate;
(iv) a third horizontal direction sensor disposed on the substrate; and
(v) a flux concentrator disposed on the third horizontal direction sensor,
wherein the flux concentrator is in cooperation with the third horizontal direction sensor to realize a function of a Z-axis sensor;
(b) realizing the x-axis sensor by the first horizontal direction sensor;
(c) realizing the y-axis sensor by the second horizontal direction sensor; and
(d) realizing the z-axis sensor by the third horizontal direction sensor and the flux concentrator.

13. The method of claim 12, wherein an insulating layer is disposed between the first horizontal direction sensor, the second horizontal direction sensor, the third horizontal direction sensor and the flux concentrator.

14. The method of claim 12, wherein the flux concentrator comprises a soft magnetic material.

15. The method of claim 12, wherein the third horizontal direction sensor comprises two groups of sensors:
(a) a first sensor group; and
(b) a second sensor group,
wherein the first sensor group comprises a first AMR magnetoresistive bar and a plurality of first current bias conductor bars forming a certain angle with the first AMR magnetoresistive bar; and the second sensor group comprises a second AMR magnetoresistive bar and a plurality of second current bias conductor bars forming a certain angle with the second AMR magnetoresistive bar.

16. The method of claim 12, wherein the first horizontal direction sensor, the second horizontal direction sensor, and the third horizontal direction sensor comprise at least two groups of sensors, respectively.

17. The method of claim 12, wherein the at least two groups of sensors have the same structure.

18. The method of claim 12, wherein the monolithic tri-axis anisotropic magnetoresistive (AMR) sensor functions as an electronic compass.

19. An electronic device using a monolithic tri-axis anisotropic magnetoresistive (AMR) sensor for sensing magnetism field according to claim 12.

20. The electronic device of claim 19, wherein the monolithic tri-axis AMR sensor functions as an electronic compass.
